(19) United States
(12) Patent Application Publication
(10) Pub. No.: US 2026/0299053 A1
(43) Pub. Date: Oct. 1, 2026

(54) INTEGRATED CIRCUIT FOR MEASURING MAGNETIC FIELDS AND FOR MEASURING THE POLARISATION OF LIGHT

(71) Applicant: POLDI microelectronics GmbH, Recklinghausen (DE)

(72) Inventor: Günter GRAU, Dorsten (DE)

(21) Appl. No.: 19/143,841

(22) PCT Filed: Dec. 29, 2023
(86) PCT No.: PCT/EP2023/088014

§ 371 Date: Sep. 10, 2025

(30) Foreign Application Priority Data
Dec. 31, 2022 (EP) 22000270.3

(51) Int. Cl. G01R 33/00; G01J 4/04

(52) U.S. Cl. CPC G01R 33/0088; G01J 4/04

(57) ABSTRACT

An integrated circuit for measuring magnetic fields and the polarization of incident light having at least one magnetic-field sensing component, at least one magnetic component, which is arranged cooperating with the magnetic-field sensing component as a structural unit, devices configured to draw a conclusion relating to variations of the magnetic field from the signals of the magnetic-field sensing component, at least two polarization-sensitive sensors with differing alignment of polarization planes, devices configured to draw a conclusion relating to the polarization of the incident light from the signals of the polarization-sensitive sensors, and at least one sensing element arranged cooperating with a polarization filter to form one of the polarization-sensitive sensors as a structural unit. The polarization-sensitive filter of the polarization-sensitive sensor arranged as a structural unit has a specifically selected extent and orientation. And, the polarization filter has grating structures generated by lithographic methods in at least one fabrication plane.

### BACKGROUND OF INVENTION

### Field of Invention

The present invention relates to an integrated circuit for measuring magnetic fields and for measuring the polarization of light and to an apparatus for measuring magnetic fields.

### Brief Description of Related Art

The known prior art (DE 2143326A 1 , DE 2143327A 1 ), on which the invention is based, relates to an integrated circuit as claimed in the first claim of the application.

In order for instance to record movements or to count revolutions, besides optical encoders and magnetic sensors based for example on the Hall effect or GMR/TMR effect, so-called Wiegand sensors 100 (FIG. 1a) are also employed, which operate with a magnetic material having pronounced hysteresis properties: the Wiegand wire 101. A Wiegand wire is modified in its structure during production, initially by heat treatment and subsequently by repeated torsion, so that it has a soft-magnetic core 103 and a hard-magnetic shell 102. When exposed to an external magnetic field, the soft-magnetic core is aligned first, while the hard-magnetic shell initially keeps its internal magnetization because of its high remanence (DE 2143326 A1, DE 2143327A 1 ). The shell does not reverse the polarity of its magnetic orientation until a critical field strength is exceeded, although it then does so almost instantaneously regardless of the rate of change of the external magnetic field. By an induction coil 104 arranged around the Wiegand wire, a steep-edged signal with a significant amplitude (up to a few volts for the normal sensors on the market) is thus created. With the aid of the Wiegand wire, even a very slow movement can therefore be recorded very simply. Sometimes, the signals generated are so strong that they can even be used for the energy supply of the circuit (energy harvesting), since expensive amplifiers are not needed for the strong signals and the energy is sufficient for operating a counter having a nonvolatile memory. For instance, the rotation of a magnet 105 in the vicinity of the sensor may be recorded by counting pulses, each approach by alternating magnetic poles generating a pulse 110 (FIG. 1b). The sign of the pulses depends on the direction of the magnetization reversal of the hard-magnetic shell.

One challenge with the Wiegand sensor is into alia the complicated production process of the Wiegand wire. The process requires special parameters in relation to material, diameter and treatment. Furthermore, the Wiegand sensor uses a slim induction coil extending around the Wiegand wire, in order to be able to convert as much of the released energy as possible into an electrical signal. This coil is in principle constructed like a relay coil. The entire sensor, consisting of the Wiegand wire and the induction coil, is typically potted and provided with contact pins. It is thus a so-called discrete, and often wired, component device with dimensions of the order of 5×5×15 mm, and is therefore substantially larger and heavier than many semiconductor sensors.

Some magnetic sensors use field plates in order to influence the direction of a magnetic field in the vicinity of the sensor or to produce passive amplification.

One example of this involves 3D Hall sensors with an integrated field concentrator, as has been described for example by C. Schott, R. Racz, S. Huber: CMOS Three Axis Hall Sensor and Joystick Application, Proceedings IEEE Sensors Conference 2004, Vienna, Austria, 10.25-27.2004. This case, however, uses soft-magnetic materials that have as little hysteresis as possible so that an accurate signal of the instantaneously applied magnetic field can be measured.

A challenge therefore exists to improve the prior art.

### BRIEF SUMMARY OF THE INVENTION

The invention is based on the object of configuring and developing the known integrated circuit in such a way that further optimization can be achieved in respect of the aforementioned challenge.

The above object is achieved by the features of the first claim, namely an integrated circuit for measuring magnetic fields and for measuring the polarization of light,
having at least one magnetic-field sensing component,
having at least one magnetic component, which is arranged cooperating with the sensing component as a structural unit,
wherein the integrated circuit contains devices that are configured to draw a conclusion relating to variations of the magnetic field from the signals of the magnetic-field sensing component,
having at least two polarization-sensitive sensors with differing alignment of the polarization planes,
wherein the integrated circuit contains devices that are configured to draw a conclusion relating to the polarization of the incident light from the signals of the polarization-sensitive sensors,
having at least one sensing element that is arranged cooperating with a polarization filter to form one of the polarization-sensitive sensors as a structural unit,
wherein the polarization-sensitive filter of the polarization-sensitive sensor arranged as a structural unit has a specifically selected extent and orientation,
wherein the polarization filter has grating structures generated by lithographic methods in at least one fabrication plane.

What is essential is the fundamental concept of producing a sensor comparable to the Wiegand sensor, which is constructed and can be integrated in a planar fashion. In particular, the production of the sensor is as compatible as possible with production steps of semiconductors, or fits typical packages for semiconductors, and can be fabricated in an automated fashion in large numbers. The finished sensor can easily be processed with automatic pick-and-place machines.

According to a further teaching as claimed in another claim, to which independent importance is attributed, an integrated circuit for measuring magnetic fields and for measuring the polarization of light is claimed,
having at least one magnetic-field sensing component,
having at least one magnetic component, which is arranged cooperating with the sensing component as a structural unit,
wherein the at least one magnetic component has a hard-magnetic zone with magnetic hysteresis,
wherein the field lines of at least one magnetic component at least partially permeate a magnetic-field sensing component,
wherein the integrated circuit contains devices that are configured to draw a conclusion relating to variations of the magnetic field from the signals of the magnetic-field sensing component,
having at least two polarization-sensitive sensors with differing alignment of the polarization planes,
wherein the integrated circuit contains devices that are configured to draw a conclusion relating to the polarization of the incident light from the signals of the polarization-sensitive sensors,
having at least one sensing element that is arranged cooperating with a polarization filter to form one of the polarization-sensitive sensors as a structural unit,
wherein the polarization-sensitive filter of the polarization-sensitive sensor arranged as a structural unit has a specifically selected extent and orientation,
wherein the polarization filter has grating structures generated by lithographic methods in at least one fabrication plane and/or wiring plane,
wherein there are opaque walls between the regions with grating structures, which prevent influencing of neighboring sensors in the event of oblique light incidence,
wherein the opaque walls are produced by vias or contacts.

All comments relating to the proposed integrated circuit according to the first teaching may be referred to.

According to a further teaching as claimed in another claim, to which independent importance is attributed, an apparatus for measuring magnetic fields is claimed, having, in particular consisting of, at least one sensing component and at least one magnetic component.

What is essential in the apparatus is that
at least one magnetic component has a hard-magnetic zone with magnetic hysteresis,
at least one sensing component has a magnetic-field sensor,
the field lines of at least one magnetic component at least partially permeate a magnetic-field sensing component,
the apparatus is suitable for recording discrete events, in particular for counting.

All comments relating to the proposed integrated circuit according to the first teaching and the second teaching may be referred to.

Dependent claims define advantageous embodiments of the proposed apparatus.

### BRIEF DESCRIPTION OF THE DRAWINGS

The invention is explained in more detail below with the aid of a drawing, which represents merely exemplary embodiments.

FIG. 1a shows a perspective view of a Weigand sensor and rotatable magnet.

FIG. 1b shows an exemplary time profile of magnetic pulses for a Weigand sensor signal for 3/2 revolutions of a rotatable magnet.

FIG. 2a shows a perspective view of an exemplary planar sensor arrangement with laminated sheets.

FIG. 2b shows a plan view of a sensor arrangement with tessellated arrangement, or position-dependent material properties.

FIG. 3a shows an exemplary sensor arrangement in an integrated circuit package with a magnetic component below a sensor component.

FIG. 3b shows an exemplary sensor arrangement in an integrated circuit package with a magnetic component above a sensor component.

FIG. 4 shows an exemplary arrangement with a main coil and secondary coils.

FIG. 5 shows an exemplary arrangement comprising sensor array and multipole strip magnet.

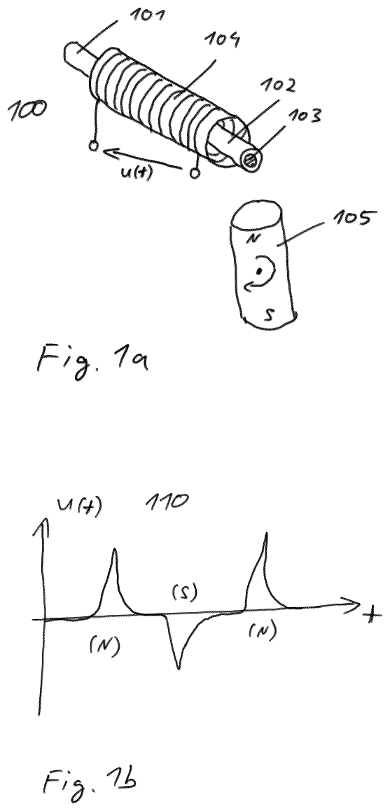

### DETAILED DESCRIPTION OF THE INVENTION

The exemplary embodiment which is represented in figures, and to this extent is preferred, relates to an integrated circuit for measuring magnetic fields and for measuring the polarization of light,
having at least one magnetic-field sensing component,
having at least one magnetic component, which is arranged cooperating with the sensing component as a structural unit,
wherein the integrated circuit contains devices that are configured to draw a conclusion relating to variations of the magnetic field from the signals of the magnetic-field sensing component,
having at least two polarization-sensitive sensors with differing alignment of the polarization planes,
wherein the integrated circuit contains devices that are configured to draw a conclusion relating to the polarization of the incident light from the signals of the polarization-sensitive sensors,
having at least one sensing element that is arranged cooperating with a polarization filter to form one of the polarization-sensitive sensors as a structural unit,
wherein the polarization-sensitive filter of the polarization-sensitive sensor arranged as a structural unit has a specifically selected extent and orientation,
wherein the polarization filter has grating structures generated by lithographic methods in at least one fabrication plane.

Further, an integrated circuit for measuring magnetic fields and for measuring the polarization of light is proposed,
having at least one magnetic-field sensing component,
having at least one magnetic component, which is arranged cooperating with the sensing component as a structural unit,
wherein the at least one magnetic component has a hard-magnetic zone with magnetic hysteresis,
wherein the field lines of at least one magnetic component at least partially permeate a magnetic-field sensing component,
wherein the integrated circuit contains devices that are configured to draw a conclusion relating to variations of the magnetic field from the signals of the magnetic-field sensing component,
having at least two polarization-sensitive sensors with differing alignment of the polarization planes,
wherein the integrated circuit contains devices that are configured to draw a conclusion relating to the polarization of the incident light from the signals of the polarization-sensitive sensors,
having at least one sensing element that is arranged cooperating with a polarization filter to form one of the polarization-sensitive sensors as a structural unit,
wherein the polarization-sensitive filter of the polarization-sensitive sensor arranged as a structural unit has a specifically selected extent and orientation,
wherein the polarization filter has grating structures generated by lithographic methods in at least one fabrication plane and/or wiring plane,
wherein there are opaque walls between the regions with grating structures, which prevent influencing of neighboring sensors in the event of oblique light incidence,
wherein the opaque walls are produced by vias or contacts.

All comments relating to the proposed integrated circuit according to the first teaching may be referred to.

Further, here and preferably, the sensing and magnetic components are arranged in a planar fashion and are combined to form a module.

“Planar” means in the present context that the magnetic component lies in a different plane, parallel thereto, than the sensing component, i.e. above or below the latter, and consequently there is no intersection between the two, as in the case of a Wiegand sensor a coil as the sensing component is typically wound around the magnetic component. Although fabrication technologies for integrated circuits have several fabrication planes, the coils that may be produced in an integrated circuit are flat coils with few planes connected by vias and are therefore likewise planar. Coils and polarization filter gratings are in this case produced in the same fabrication planes as are used for the wiring of the circuit elements of the integrated circuit.

Further, here and preferably, the magnetic component has at least one layer stack with differing magnetic hardness.

Further, here and preferably, the magnetic component has at least one lateral arrangement comprising zones with differing magnetic hardness.

Further, here and preferably, a plurality of magnetically hard zones and a plurality of magnetic-field sensors are arranged in such a way that they form a planar arrangement with a plurality of integrated circuits for measuring magnetic fields.

Further, here and preferably, the sensing component is an integrated circuit having an optional nonvolatile memory.

According to the proposal, it is possible to produce a sensor comparable to the Wiegand sensor, which is constructed and can be integrated in a planar fashion. In particular, the production of the sensor is as compatible as possible with production steps of semiconductors, or fits typical packages for semiconductors, and can be fabricated in an automated fashion in large numbers. The finished sensor can easily be processed with automatic pick-and-place machines.

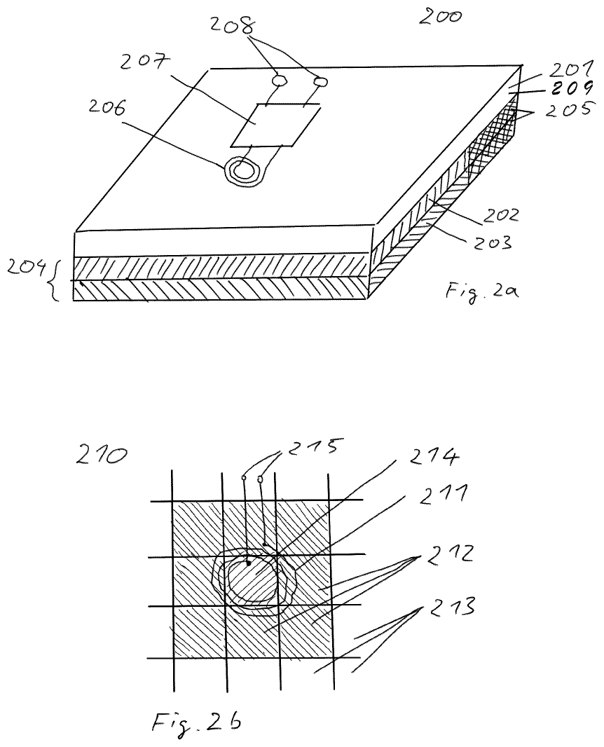

According to the invention, two components are required for this purpose, namely a magnetic component with particular hysteresis properties, in particular with at least one hard-magnetic zone, and a sensing component, which are arranged in immediate proximity concentrically with the magnetic component to form a structural unit (FIG. 2a/b).

Although a monolithically integrated solution would be particularly advantageous, it is difficult to produce the magnetic component with the process steps for the production of an integrated circuit. A comparatively large amount of material is needed in order to store sufficient energy that can be detected by the sensing component. Instead of sputtering (layer thicknesses in the um range), the use of sheets is therefore advantageous in order to be able to use layer thicknesses of from a few ten of um to a few hundreds of μm.

For the magnetic component, according to the invention, in a first variant laminated sheets with differing magnetic hardness are employed (FIG. 2a—see the accompanying list of reference signs for a more detailed identification of the subject matter shown therein). The soft-magnetic sheets (one or more) serve as a field concentrator, while the hard-magnetic sheets (at least one) provide the energy store. The latter experiences magnetization reversal by the external magnetic field of sufficient strength, and generates a steep-edged signal for the sensor component at the tipping point. Under certain circumstances, the soft-magnetic component may be obviated if the hard-magnetic material already has a substantially square-wave hysteresis curve with a high remanence and a pronounced area under the hysteresis curve. In order to reduce stray losses, the hard-magnetic sheet should be closest to the sensor component.

In a second embodiment, interconnected sheet segments with differing magnetic hardness are employed, which to simplify matters may also be treated as “tiles” (FIG. 2b—see the accompanying list of reference signs for a more detailed identification of the subject matter shown therein). They so to speak emulate the concentric arrangement of the Wiegand wire, but may be optimized independently of one another by different processing steps or materials. These sheet segments may be produced for example by pressing or laser cutting, in which case in particular honeycombed elements besides rectangular shapes are useful for an expedient arrangement. Since the processing (for example pressing, laser cutting) may modify the magnetic properties, it is expedient to subject at least the soft-magnetic elements to a secondary treatment, for instance a heat treatment for uniform softening. This may advantageously take place in an external magnetic field in order to align the magnetic domains of the material (preferentially, perpendicularly to the surface). Since retrospective hardening of the small elements is difficult to implement, different materials may advantageously be employed. For example, expanded nickel foil with its pronounced remanence is highly suitable for hard-magnetic elements, while for example heat-treated mu-metal sheet is suitable for soft-magnetic elements.

In a further embodiment, only a single sheet is used, which is locally modified in its magnetic properties by selective treatment. For instance, a sheet previously hardened (for example by mechanical processing) may be selectively softened by local heating (for example selective heat treatment by laser exposure). Different variants of the treatment are possible, including for instance selective hardening by ion implantation. However, laser treatment appears to be particularly easy and efficient to implement. Since local material processing is easier with thinner sheets, larger thicknesses may in turn be produced by using a layer stack of identically processed sheets.

The spatial extent of the magnetic component need not necessarily be the same as that of the sensor. Particularly in the case of a significantly larger sensor element (for example an integrated circuit with numerous additional functions), it may therefore be advantageous to enclose the sheet in a nonmagnetic material in order to produce a flat surface. For this purpose, both metallic materials (for example aluminum) and nonmetallic materials (for example plastic) may be used.

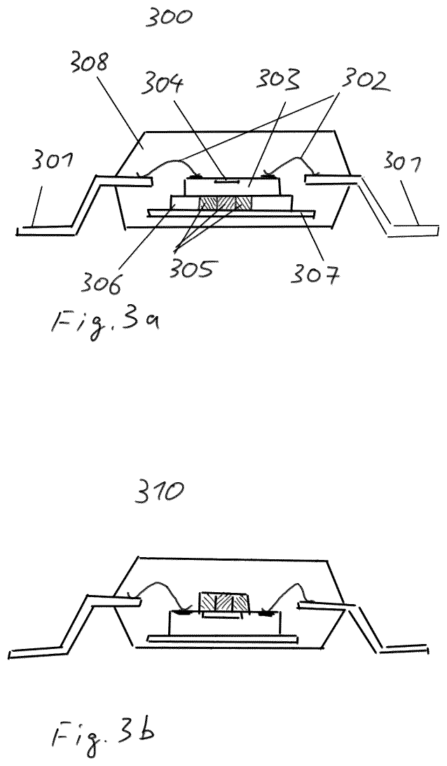

In one embodiment, the magnetic component may be fastened (for instance adhesively bonded) in a still empty chip package before the sensor component (for instance an integrated circuit or a printed circuit board) is fastened thereon (FIG. 3a—see the accompanying list of reference signs for a more detailed identification of the subject matter shown therein). In another embodiment, the package may have a suitable recess for the magnetic component, so that nonmagnetic frame elements for generating a flat mounting surface for the sensor component may be obviated. It is also conceivable that the lead frame of an IC package can itself be used as the magnetic component of the sensor.

Alternatively, the magnetic component may be fastened directly on the back side of the sensor component before the latter is then processed further or used as a unit, or the magnetic component is fastened on the front side of the sensor component (for example on the passivation of an integrated circuit) (FIG. 3b—see the accompanying list of reference signs for a more detailed identification of the subject matter shown therein). These steps may for instance be carried out even before singulation of the chips from a wafer or printed circuit boards from a panel. The front side of the sensor component has, particularly in the case of microelectronic circuits, the advantage that for example an integrated coil is closer to the magnetic material and therefore less stray losses occur. This variant is recommendable in particular when the magnetic component is much smaller than the sensing component. The structuring and arrangement of the magnetic component may in this case also take place in a wafer fashion so that after singulation, for example by laser cutting, the transfer of the magnetic components onto the sensing component can take place rapidly and economically, for example by micro-transfer printing (μTP). The reverse route of μTP is also possible in the case of a small sensor component.

When the magnetic component is arranged on the back side of the sensor component, the latter should be as thin as possible, i.e. an integrated circuit should be thinned. This is also advantageous in order to reduce the thickness of the entire arrangement, so that for example an IC package does not become overly thick.

A further embodiment uses two magnetic components per sensor component, namely one on the upper side and one on the lower side. In the broadest of terms, the sensor component is then located in a gap of a very short I-core. In this way, with a sufficiently thin sensor component, a stronger flux through the sensor can be generated. It is not necessary, although it is possible, for there to be a hard-magnetic component on both sides of the sensor component.

The sensor component may in principle operate with all possible magnetic-field sensors, i.e. for example also with Hall sensors or GMR/AMR sensors. For energy-saving detection, as well as in particular for energy harvesting, a passive sensor in the form of an induction coil is, however, recommendable. In the case of an integrated circuit, the latter may be produced as an integrated coil in the metallization of the integrated circuit, in which case, in contrast to RF coils, the quality factor is of secondary importance. Rather, the coil geometry should be optimized in such a way that the maximum flux can be received from the spontaneous magnetization reversal, so that a voltage that is as high as possible can be generated. For this purpose, in particular, a large number of turns may be produced in a small space on the thin lower metallization layers. Nevertheless, coils may also be envisioned for example in finely structured printed circuit boards.

Since, in contrast to the Wiegand sensor, the sensor component now lies next to the magnetic component (instead of surrounding it), it is more difficult to avoid stray losses. In particular, a coil that is too largely dimensioned will receive less signal than a small one because field lines both from the central main field and from the peripheral stray field cross the coil surface and the signals therefore partially cancel out. In contrast to the Wiegand wire, which due to the way in which it is produced has a hard-magnetic shell, in this case a hard-magnetic center, which may be enclosed by a soft-magnetic concentrator, is advantageous since the sensor signal emanates from the spontaneous magnetization reversal of a hard-magnetic material.

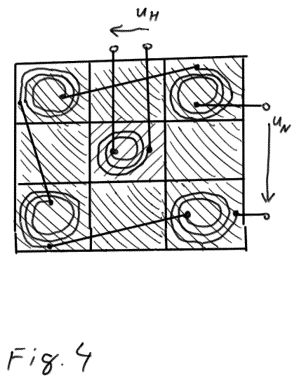

The possibilities of integration make it possible, besides the centrally arranged coil for the field of the hard-magnetic component (main coil), also to arrange coils at the periphery. Depending on the location and arrangement, these primarily pick up stray fields or external fields (FIG. 4—see the accompanying list of reference signs for a more detailed identification of the subject matter shown therein). A differential signal is therefore obtained, so that it is possible to distinguish whether the hard-magnetic component has experienced magnetization reversal or a different event has occurred. This can increase the resistance of the sensor against interference.

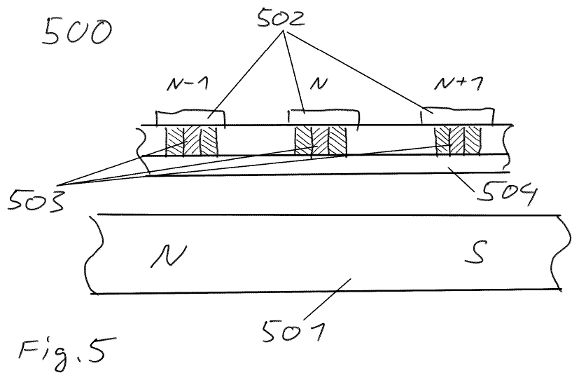

The planar arrangement proposed here offers further advantages in particular by the use of local material processing (for instance laser treatment) in the magnetic component and by the possibilities of intricate fabrication for integrated circuits or finely structured printed circuit boards in the sensor component. Arrangements of a plurality of sensors in one dimension (chain) or two dimensions (array) may be produced very simply on condition that the hard-magnetic zones are sufficiently far away from one another so that they do not mutually interfere (FIG. 5 see the accompanying list of reference signs for a more detailed identification of the subject matter shown therein). This may be utilized in order to generate a redundancy (a plurality of independent sensors deliver a signal almost simultaneously) or to generate a stronger or temporally extended signal (for instance by concatenating a plurality of neighboring sensor signals in series).

Moreover, precisely by utilizing the small time differences in the response of neighboring hard-magnetic zones, it is possible to record the movement direction of the external magnetic field and therefore, for instance, the direction of rotation of a shaft. In the case of discrete Wiegand sensors, this would require a significant overall size and therefore a much stronger mechanical movement than in the case of the present invention. An arrangement comprising a plurality of sensors may also be used for simpler detection of relatively small movements, on condition that not all the individual elements have yet adapted to the external magnetic field and the pole pair spacings of the magnets are of the order of magnitude of the extent of the sensor field. If a pole wheel (a wide variety of embodiments may be used, from rotating bar magnets to a multipole magnetic strip) is combined with a circumferential arrangement comprising multichannel sensors, a passive magnetic angle encoder may be produced.

In this case, it is recommendable to produce the sensor as a flexible arrangement in the form of a strip, which may be placed concentrically around a pole wheel. For this purpose, it is advantageous that the sensor component is also configured to be flexible (for example integrated coils on a flexible printed circuit which is connected to a metal strip, optionally with integrated circuits that are fastened on a flexible printed circuit board). This is recommendable in particular for large diameters of the magnetic component. For smaller diameters, on the other hand, a planar annular arrangement is more advantageous.

Passive linear encoders (position sensors) may also be produced in this way. Since the resolution based on this effect is limited, a combination with active sensors may be used in order to achieve a more accurate position or angle determination between the magnetic pulses. It is conceivable that, for example, a batteryless caliper gauge or encoder may thereby be produced, since the magnetic pulses can be generated in a much greater number, or at a much higher frequency, than with discrete Wiegand sensors.

The fact that the planar sensor proposed here is made much smaller, and can also operate with an integrated coil, offers the possibility of single-chip sensors that also enable precise angle or position determination, besides the counting function and possible direction detection. On the one hand, combinations of the sensor proposed here with active magnetic sensors (Hall, GMR/TMR, etc.) are possible, in which case the active sensor may either measure the instantaneous magnetic field in the region of the magnetic component, or may preferably measure the strength and direction of the undistorted external magnetic field some way away from the magnetic field, in order for instance to enable a more accurate position determination on a magnetic multipole strip or wheel. It may moreover also be combined with other sensor technologies. In particular when the magnetic component is located on the back side of the sensor component, which is preferably embodied as an integrated circuit, the front side of the sensor component may also be used for optical sensors. Particularly advantageous is the combination of the magnetic sensor proposed here with a polarization sensor (DE 102005031966A1 , EP 1902334A1 ), which enables exact rotational angle determination with little expense. In this combination, it is possible to produce a single-chip sensor for multi-turn transducers which requires scarcely any adjustment, has a high accuracy, and ideally performs the counting of magnetic pulses even without an external power supply (by energy harvesting and a nonvolatile memory). If the magnetic component is located below the sensor component, the optical sensor may also be located directly above the latter and the magnetic sensor component may also surround the optical sensor, and electronic circuits may likewise be arranged at the center of the coil. The optical sensor may naturally also be located next to the magnetic sensor component. In this case, there is no restriction in terms of the configuration of the magnetic component.

It is particularly advantageous that both the magnetic sensor component and the polarization filters, which are required for an optical polarization sensor, are produced in the metallization planes of an integrated circuit that are used for the wiring of the integrated circuit. In this way, the proposed sensor may be produced without modification by many different fabrication processes, and it is merely necessary that the magnetic component is fastened on the integrated circuit after the IC production, or the two are arranged cooperating with one another in a package.

The respective figures correspondingly also show an apparatus for measuring magnetic fields, having, in particular consisting of, at least one sensing component and at least one magnetic component.

What is essential in the apparatus is that
at least one magnetic component has a hard-magnetic zone with magnetic hysteresis,
at least one sensing component has a magnetic-field sensor,
the field lines of at least one magnetic component at least partially permeate a magnetic-field sensing component,
the apparatus is suitable for recording discrete events, in particular for counting.

All comments relating to the proposed integrated circuit according to the first teaching and the second teaching may be referred to.

Further, here and preferably, the sensing and magnetic components are arranged in a planar fashion and are combined to form a module.

Further, here and preferably, the magnetic component has at least one layer stack with differing magnetic hardness.

Further, here and preferably, the magnetic component has at least one lateral arrangement comprising zones with differing magnetic hardness.

Further, here and preferably, a plurality of magnetically hard zones and a plurality of magnetic-field sensors are arranged in such a way that they form a planar arrangement with a plurality of apparatuses for measuring magnetic fields.

Further, here and preferably, the sensing component is an integrated circuit
having at least one electronic circuit
having at least one sensor
having an optional nonvolatile memory.

Further, here and preferably, the at least one further sensor is a polarization sensor.

### LIST OF REFERENCE SIGNS

The list below identifies the reference signs used to identify subject matter shown in the accompanying drawing figures:
100 Wiegand sensor and rotatable magnet
101 Wiegand wire
102 hard-magnetic shell
103 soft-magnetic core
104 induction coil
105 magnet
110 exemplary time profile of sensor signal for 3/2 revolutions
200 planar sensor arrangement with laminated sheets
201 sensor component (for example integrated circuit)
202 magnetic material (for example hard-magnetic)
203 magnetic material (for example soft-magnetic)
204 magnetic component
205 filler material (nonmagnetic)
206 (integrated) coil
207 signal processing
208 terminals
210 plan view of a sensor arrangement with tessellated arrangement, or position-dependent material properties
211 induction coil
212 preferably soft-magnetic material
213 nonmagnetic filler material
214 preferably hard-magnetic material
215 terminals
300 sensor arrangement in IC package with magnetic component below sensor component
301 lead
302 bonding wire
303 integrated circuit
304 sensor component (coil)
305 magnetic component
306 filler material
307 lead-frame pad
308 IC package (for example epoxide/LCP)
310 sensor arrangement in IC package with magnetic component above sensor component
400 arrangement with main coil and secondary coils
500 arrangement comprising sensor array and multipole strip magnet
501 strip magnet
502 sensor components
503 magnetic components
504 frame

1-14. (canceled)

15. An integrated circuit for measuring magnetic fields and for measuring the polarization of incident light, the integrated circuit comprising:
at least one magnetic-field sensing component;
at least one magnetic component, which is arranged cooperating with the magnetic-field sensing component as a structural unit;
devices that are configured to draw a conclusion relating to variations of the magnetic field from the signals of the magnetic-field sensing component;
at least two polarization-sensitive sensors with differing alignment of the polarization planes;
devices that are configured to draw a conclusion relating to the polarization of the incident light from the signals of the polarization-sensitive sensors; and
at least one sensing element that is arranged cooperating with a polarization filter to form one of the polarization-sensitive sensors as a structural unit;
wherein the polarization-sensitive filter of the polarization-sensitive sensor arranged as a structural unit has a specifically selected extent and orientation, and
wherein the polarization filter has grating structures generated by lithographic methods in at least one fabrication plane.

16. The integrated circuit as claimed in claim 15, wherein the sensing and magnetic components are arranged in a planar fashion and are combined to form a module.

17. The integrated circuit as claimed in claim 15, wherein the magnetic component has at least one layer stack with differing magnetic hardness.

18. The integrated circuit as claimed in claim 15, wherein the magnetic component has at least one lateral arrangement comprising zones with differing magnetic hardness.

19. A plurality of integrated circuits for measuring magnetic fields and for measuring the polarization of incident light as claimed in claim 15, wherein a plurality of magnetically hard zones and a plurality of magnetic-field sensors are arranged in such a way that they form a planar arrangement with the plurality of integrated circuits for measuring magnetic fields and for measuring the polarization of incident light.

20. The integrated circuit as claimed in claim 15, wherein the magnetic-field sensing component is an integrated circuit having an optional nonvolatile memory.

21. An integrated circuit for measuring magnetic fields and for measuring the polarization of incident light, the integrated circuit comprising:
at least one magnetic-field sensing component;
at least one magnetic component, which is arranged cooperating with the magnetic-field sensing component as a structural unit, wherein said at least one magnetic component having a hard-magnetic zone with magnetic hysteresis and wherein field lines of at least one magnetic component at least partially permeate the magnetic-field sensing component;
devices that are configured to draw a conclusion relating to variations of the magnetic field from the signals of the magnetic-field sensing component;
at least two polarization-sensitive sensors with differing alignment of the polarization planes;
devices that are configured to draw a conclusion relating to the polarization of the incident light from the signals of the polarization-sensitive sensors; and
at least one sensing element that is arranged cooperating with a polarization filter to form one of the polarization-sensitive sensors as a structural unit;
wherein the polarization-sensitive filter of the polarization-sensitive sensor arranged as a structural unit has a specifically selected extent and orientation,
wherein the polarization filter has grating structures generated by lithographic methods in at least one fabrication plane and/or wiring plane, and
wherein there are opaque walls between regions with grating structures, which prevent influencing of neighboring sensors in the event of oblique light incidence, and
wherein the opaque walls are produced by vias or contacts.

22. The integrated circuit as claimed in claim 21, wherein the sensing and magnetic components are arranged in a planar fashion and are combined to form a module.

23. The integrated circuit as claimed in claim 21, wherein the magnetic component has at least one layer stack with differing magnetic hardness.

24. The integrated circuit as claimed in claim 21, wherein the magnetic component has at least one lateral arrangement comprising zones with differing magnetic hardness.

25. A plurality of integrated circuits for measuring magnetic fields and for measuring the polarization of incident light as claimed in claim 21, wherein a plurality of magnetically hard zones and a plurality of magnetic-field sensors are arranged in such a way that they form a planar arrangement with the plurality of integrated circuits for measuring magnetic fields and for measuring the polarization of incident light.

26. The integrated circuit as claimed in claim 21, wherein the magnetic-field sensing component is an integrated circuit having an optional nonvolatile memory.

27. An apparatus for measuring magnetic fields comprising:
at least one sensing component; and
at least one magnetic component;
wherein the at least one magnetic component has a hard-magnetic zone with magnetic hysteresis,
wherein the at least one sensing component has a magnetic-field sensor,
wherein field lines of the at least one magnetic component at least partially permeate the magnetic-field sensor of the a least one sensing component, and
wherein the apparatus is configured to record discrete events.

28. The apparatus according to claim 27, wherein the discrete events are magnetic pulses, which are counted by the apparatus.

29. The apparatus for measuring magnetic fields as claimed in claim 27, wherein the sensing and magnetic components are arranged in a planar fashion and are combined to form a module.

30. The apparatus for measuring magnetic fields as claimed in claim 27, wherein the magnetic component has at least one layer stack with differing magnetic hardness.

31. The apparatus for measuring magnetic fields as claimed in claim 27, wherein the magnetic component has at least one lateral arrangement comprising zones with differing magnetic hardness.

32. The apparatus for measuring magnetic fields as claimed in one of claims 27, wherein a plurality of magnetically hard zones and a plurality of magnetic-field sensors are arranged in such a way that they form a planar arrangement with a plurality of apparatuses for measuring magnetic fields as claimed in claim 27.

33. The apparatus for measuring magnetic fields as claimed in one of claims 27, wherein the sensing component is an integrated circuit
having at least one electronic circuit
having at least one sensor
having an optional nonvolatile memory.

34. The apparatus for measuring magnetic fields as claimed in claim 33, wherein the at least one further sensor is a polarization sensor.
